(19) United States
(12) Patent Application Publication
(10) Pub. No.: US 2025/0167675 A1
(43) Pub. Date: May 22, 2025

(54) TRANSISTOR UNIT FOR A POWER CONVERTER, POWER CONVERTER AND METHOD FOR MANUFACTURING A POWER CONVERTER

(71) Applicant: ZF Friedrichshafen AG, Friedrichshafen (DE)

(72) Inventors: Manuel Raimann, Salem (DE); Thomas Bosch, Horgenzell (DE); Pengshuai Wang, Eriskirch (DE)

(73) Assignee: ZF Friedrichshafen AG, Friedrichshafen (DE)

(21) Appl. No.: 18/956,415

(22) Filed: Nov. 22, 2024

(30) Foreign Application Priority Data
Nov. 22, 2023 (DE) 10 2023 211 627.8

(51) Int. Cl. H02M 3/00; H05K 7/20

(52) U.S. Cl. CPC H02M 3/003; H05K 7/209

(57) ABSTRACT

A transistor unit for a power converter has a printed circuit board populated with numerous power transistors, wherein the printed circuit board has at least one electrical wire for connecting the transistor unit inside the power converter, a thermal conductor on the power transistors for thermally coupling the transistor unit to a cooling unit for the power converter, and a transistor housing for at least partially housing the printed circuit board.

### CROSS-REFERENCE TO RELATED APPLICATION

This application claims priority to German Patent Application No. 10 2023 211 627.8, filed on Nov. 22, 2023, the entirety of which is hereby fully incorporated by reference herein.

### TECHNICAL FIELD

The present disclosure relates to a transistor unit for a power converter, a power converter, and a production method for obtaining the power converter.

### BACKGROUND

Power converters are used in many different fields and for different apparatuses or machines, including those used in the field of electric mobility, which is currently becoming increasingly more important.

### SUMMARY

The present disclosure results in an improved transistor unit for a power converter, an improved power converter, and an improved production method for obtaining the power converter in accordance with the independent claims. Advantageous embodiments can be derived from the dependent claims and the following description.

The present approach results in the most efficient use of the available installation space in a power converter. This particularly includes creating as much space as possible for numerous electrical components. Depending on the design, the size of the power converter can also be reduced.

A transistor unit for a power converter is proposed that contains a printed circuit board populated with numerous power transistors, which has at least one electrical wire connecting the transistor unit within the power converter, a thermal conductor on the power transistors for coupling the transistor unit to a cooling unit for the power converter, and a housing for the printed circuit board.

The transistor unit can be placed vertically in a power converter for a vehicle, for example. The vehicle can be a passenger automobile, utility vehicle, or truck. The vehicle can be powered electrically. The power converter can be an inverter or a direct current converter. The printed circuit board can be populated with numerous power transistors. The electrical wire can connect the printed circuit board to other electrical components in the power converter. By way of example, the electrical wire can be connected to another printed circuit board populated with inductors. The printed circuit board have at least one electrical wire, or be connected to such. The electrical wires can advantageously pass through a hole in the transistor housing. The hole can be round our polygonal. The hole can be formed in the at least one housing element. The transistor housing can also be designed to secure a PCB in place, form an electrical insulation, and improve compression force distribution. In other words, a uniform compression force distribution to the housing can be obtained with a plastic component.

The transistor housing can have at least one housing element. There are numerous possible designs for the transistor housing, which at least partially enclose the printed circuit board. These advantageously secure a PCB in place, form an electrical insulation, and potentially improve compression force distribution.

The transistor housing can have a first and second housing element that are connected to one another, with the printed circuit board embedded between them. There can also be at least one contact window that exposes the power transistors in the first housing element, which has an outer surface facing away from the printed circuit board that is in the same plane as cooling surfaces on the power transistors. A thermal conductor can be placed on this plane that thermally couples the transistor unit to a cooling unit in the power converter. The housing elements can be referred to as two halves of a housing. The transistor housing can contain a receiving area in which the printed circuit board is held in place within the housing. The receiving structure can be formed by ribs, and the at least one contact window can be formed opposite the second housing element. This means that the at least one contact window can be formed in the first housing element for heat discharge near the receiving area.

The printed circuit board can have at least one anchoring hole with which it is secured in place between the housing elements, the second of which can have an insertion hole. The first housing element can have at least one insertion element that is inserted into the insertion hole through the anchoring hole to close the transistor housing. The at least one anchoring hole can be formed near the edge, and potentially near a corner, of the printed circuit board. This hole can be obtained by drilling or stamping. The number of anchoring holes can be the same or more than the number of insertion holes and insertion elements. This engagement between the insertion elements and the insertion holes through the anchoring holes advantageously prevents a shifting of the printed circuit board in the transistor housing.

The first housing element can also have numerous projections protruding from a plane and forming spacers, and an intermediate layer can be placed between these projections to thermally couple the transistor unit to a cooling unit in the power converter. These projections can be of a uniform height that corresponds to the thickness of the intermediate layer placed therebetween. This results in a flush contact surface for the cooling unit.

The transistor housing can also be a coating that at least partially surrounds the printed circuit board and power transistors. It can also contain a thermally conductive filler. This also secures the printed circuit board in place, forms an electrical insulation, and potentially improves compression force distribution. This coating can contain a thermally conductive, electrically insulating material.

A snubber capacitor can be placed on the printed circuit board. This snubber capacitor can improve the functioning of high speed power semiconductors made of silicon carbide (SiC) or gallium nitride (GaN).

The thermal conductor can have a laminar structure comprising at least one layer, which can contain an organic material, ceramic material, metallic material, metalized ceramic, and/or plastic. The thermal conductor can advantageously contain layers of the same thickness in the laminar structure. By way of example, the at least one layer can contain a plastic such as silicon, and/or have a phase-changing property. This results in a particularly advantageous electrical insulation for the transistor unit while thermally coupling the printed circuit board to the cooling unit. With a metallized ceramic, the mechanical and electrical connection to the transistors can be obtained with soldering, resulting in a very high thermal conductivity, while compensating for tolerances.

This laminar structure can comprise three layers, the middle of which can contain a material other than that forming the outer layers. By way of example, the middle layer can be ceramic, and the outer layers can be made of a thermal interface material (TIM).

The laminar structure can also contain three layers, the middle of which can have a different curing characteristic than the outer layers. The laminar structure can be placed on the plane formed by the housing of the transistor unit. The outer layers do not have to be fully cured at this point. The middle layer can advantageously be fully cured, however.

A power converter for a vehicle is also proposed, which contains a version of the transistor unit described herein, and a cooling unit for the transistor unit, in which the thermal conductor for the transistor unit is placed on the cooling unit.

The power converter can be a direct current converter and used in a passenger automobile. The cooling unit can contain at least one cooling channel and/or cooling fins. The transistor unit can be advantageously cooled, increasing the service life and improving the performance of the transistor unit.

The power converter can also have a housing that can also contain the transistor unit. The cooling unit can be part of the power converter housing, or integrated therein. The transistor unit can be advantageously secured on or in the power converter housing, such that it is surrounded by it.

The power converter can contain a retaining element that secures the transistor unit in the power converter and presses the transistor unit against the cooling unit. This retaining element can be formed by a spring-loaded clamp that the transistor unit can be snapped into. This advantageously results in a reliable contact between the transistor unit and the cooling unit.

The present disclosure also relates to an electric axle drive for a motor vehicle that has at least one electric machine, a transmission, and a power converter. The electric axle drive contains the power converter described herein. The transmission can form a reduction gearing for the electric machine and a differential.

The present disclosure also relates to a motor vehicle that contains an electric axle drive and/or a power converter. This motor vehicle contains the electric axle drive and/or power converter described herein.

A method for the production of one of the above variations of the power converter is also proposed, comprising a step for creating transistor unit in which a printed circuit board is populated with numerous power transistors, which is at least partially housed in a transistor housing, and the thermal conductor is placed on the power transistors, and a step for coupling the transistor unit to the cooling unit with the thermal conductor, in order to obtain the power converter.

The power converter can advantageously be assembled with this method. By way of example, a joining process for the transistor unit can be carried out in the framework of the production process to create the transistor unit.

The present disclosure shall be explained in greater detail in reference to the drawings.

### BRIEF DESCRIPTION OF THE DRAWINGS

FIG. 1 shows a schematic illustration of a motor vehicle according to one exemplary embodiment;

FIG. 2 shows a schematic illustration of an exemplary embodiment of a power converter;

FIG. 3 shows a schematic sectional view of an exemplary embodiment of a power converter;

FIG. 4 shows an exploded view of an exemplary embodiment of a transistor unit;

FIG. 5 shows a schematic sectional view of an exemplary embodiment of a transistor unit;

FIG. 6 shows a schematic sectional view of an exemplary embodiment of a transistor unit;

FIGS. 7, 8, 9, 10, and 11 show schematic illustrations of individual steps of a joining process for an exemplary embodiment of a transistor unit;

FIG. 12 shows a schematic illustration of an exemplary embodiment of an assembled transistor unit;

FIG. 13 shows a flow chart for an exemplary production process for a power converter for a vehicle;

FIG. 14 shows a schematic illustration of an exemplary embodiment of a transistor unit;

FIG. 15 shows a schematic illustration of an exemplary embodiment of a printed circuit board in a transistor unit;

FIG. 16 shows a schematic exploded view of an exemplary embodiment of a transistor unit;

FIG. 17 shows a schematic illustration of an exemplary embodiment of a transistor unit; and

FIG. 18 shows a schematic illustration of an exemplary embodiment of a transistor unit.

### DETAILED DESCRIPTION

In the following description of preferred exemplary embodiments of the present disclosure, the same or similar reference symbols are used in the various drawings for elements that have similar functions, the descriptions of which shall not be repeated.

To better understand the context of the approach, a brief overview of the thematic shall be presented here. Power transistors are often used in converters such as DC/DC converters and onboard chargers (OBCs). There are numerous designs for these, which have different types of connecting pins and cooling surfaces. One fundamental aim is to make optimal use of the available installation space and maximize performance. The installation space is substantially determined by other passive components, e.g. inductors, transformers, or capacitors. The aim of optimizing installation space and maximizing performance can be advantageously achieved with the various exemplary embodiments.

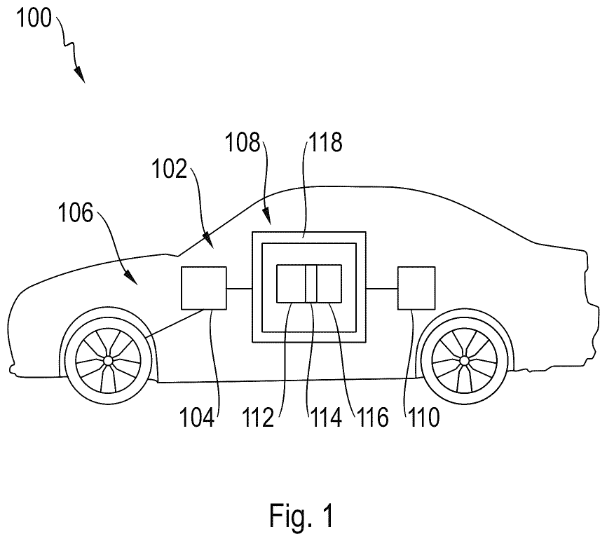

FIG. 1 shows a schematic illustration of an exemplary embodiment of a motor vehicle 100. The motor vehicle 100 is also referred to as a vehicle, and has an electric axle drive 102, which contains an electric machine 104, a transmission 106, and a power converter 108. This motor vehicle is a passenger automobile.

The electric machine 104 is also referred to as a drive unit or an electric motor, and is coupled to the transmission 106. The motor vehicle 100 also contains a power supply 110 in the form of a battery. The power converter 108 in this exemplary embodiment is interconnected between the power supply 110 and the electric machine 104.

The power converter 108 contains a capacitor and numerous switches, e.g. six switches. These components are collectively referred to as the electrical components. In addition to these and/or other electrical components, the power converter 108 in this exemplary embodiment also contains a transistor unit 112, a thermal conductor 114, and a cooling unit 116. The thermal conductor 114 is between the transistor unit 112 and the cooling unit 116 in order to thermally couple the transistor unit 112 with the cooling unit 116, and electrically insulate them from one another. The cooling unit 116 is designed to cool the transistor unit 112. The power converter 108 also has a housing 118, which also contains the transistor unit 112. The cooling unit 116 forms part of the housing 118 for the power converter, or it is integrated therein.

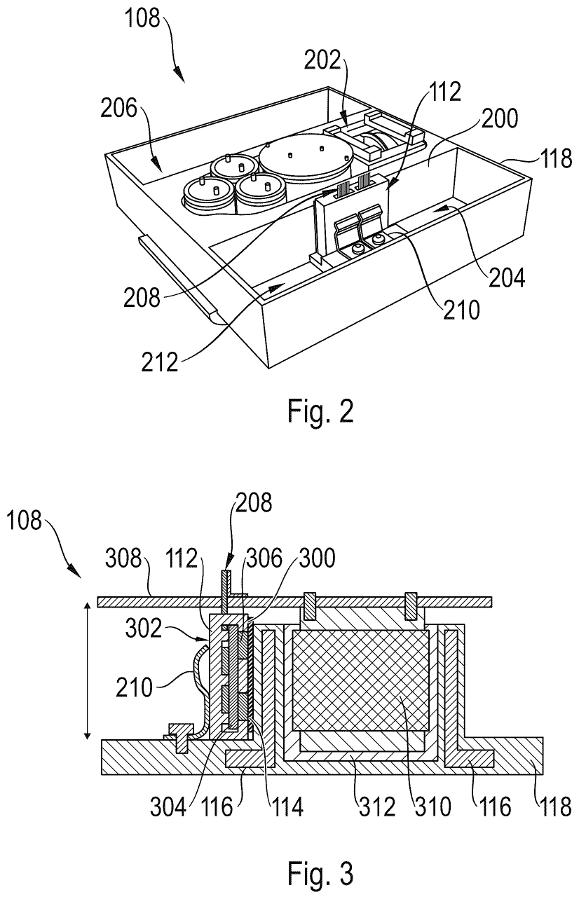

FIG. 2 shows a schematic illustration of an exemplary embodiment of a power converter 108 such as that described in reference to FIG. 1. The power converter housing 118 is partially open in FIG. 2, such that individual components, such as the electrical components 202 of the power converter 108, can be seen.

The power converter housing 118 has at least one transverse rib 200, which divides the housing 118 into two chambers 204, 206. The first chamber 204 in this exemplary embodiment is smaller than the second chamber 206. Both chambers 204, 206 are large enough to accommodate any other electronic components needed for a particular application or field of use.

The transistor unit 112 in this exemplary embodiment is on the transverse rib 200. By way of example, the cooling unit described in reference to FIG. 1 is integrated in the transverse rib 200 in order to cool the transistor unit 112. There are electrical wires 208 protruding from the transistor unit 112 on one side, which are then connected to a printed circuit board (not shown) in the transistor unit 112. The wires 208 are connected to a printed circuit board in the transistor unit 112, as shown in FIG. 3, and explained below.

The power converter 108 in this exemplary embodiment has a retaining element 210 for the transistor unit 112 that presses it against the cooling unit integrated in the transverse rib 200 in FIG. 2. The retaining element 210 is formed by at least one clamp attached to the base 212 of the power converter 108. The transistor unit 112 in this exemplary embodiment is perpendicular to the base 212 of the power converter 108.

In other words, the transistor unit 112, also referred to as a vertical power package (VPP) is perpendicular to the base 212 of the power converter 108. This results in a three-dimensional packaging that makes good use of the available space while obtaining an advantageous electrical connection and optimal thermal connection.

FIG. 3 shows a schematic sectional view of an exemplary embodiment of a power converter 108 such as that described in reference to FIGS. 1 and 2. The transistor unit 112 is also attached to the power converter housing 118 here. This power converter 108 also contains the spring-loaded retaining element 210 attached to the power converter housing, which presses the transistor unit 112 against the cooling unit 116. This retaining element 210 is attached to the power converter housing 118 by threaded fasteners, merely by way of example.

In this exemplary embodiment, the cooling unit 116 forms at least one cooling channel integrated in the power converter housing 118, such that a coolant can flow through it. A thermal conductor 114 is also shown in FIG. 3 between the cooling unit 116 and the transistor unit 112, which can also be in surface contact with a plane 300 on the transistor unit 112. This plane 300 is formed by an outer surface of the transistor housing 302 and at least one power transistor 306 on a printed circuit board 304 in the transistor housing 302.

As in FIG. 2, the transistor unit 112 has electric wires 208 that are mechanically and electrically connected to the printed circuit board 304 in the transistor unit 112 and a printed circuit board 308 in the power converter 108. At least one of these wires 208 passes through the transistor housing 302, e.g. through a hole therein.

There is also a coil unit 310 in this exemplary embodiment, which is also electrically connected to the printed circuit board 308 in the power converter 108. This coil unit 310 is also in contact with the cooling unit 116, but on the side facing away from the thermal conductor 114. The coil unit 310 is designed to generate a magnetic field. It can therefore also be referred to as a magnetic unit. The coil unit 310 is in a cup-shaped part 312 of the power converter housing 118, surrounded by the cooling unit 116.

By way of example, the thermal conductor 114 contains a thermally conductive material (TIM), e.g. containing silicon. The insulating material in the thermal conductor 114 forms a thermally conductive path with a silicon base or a phase changing material, i.e. a material with a phase-changing function.

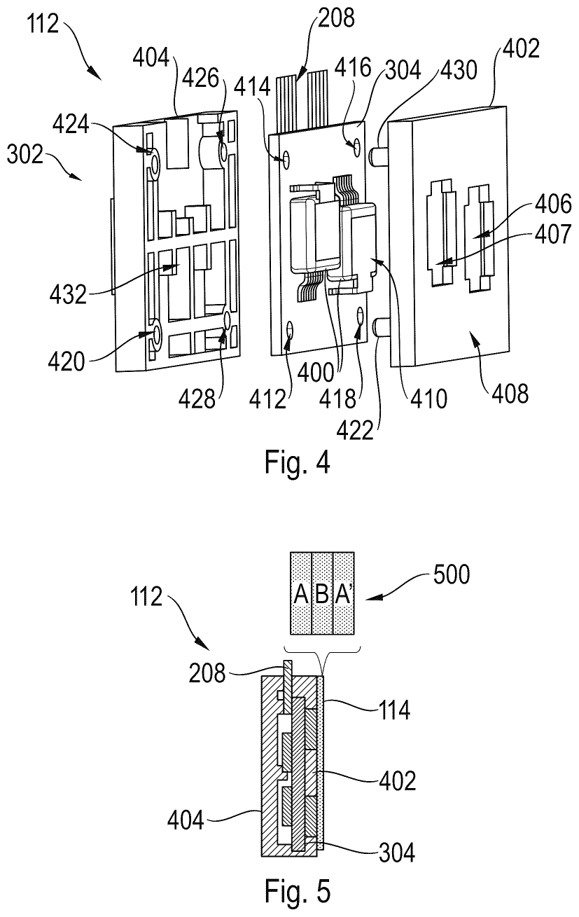

FIG. 4 shows an exploded view of an exemplary embodiment of a transistor unit 112 such as that described in reference to FIGS. 1 to 3. This transistor unit 112 also contains a printed circuit board 304 populated with numerous power transistors 400 and contains or is connected to at least one electrical wire 208 connecting it to the transistor unit 112 inside the power converter. There can also be a snubber capacitor and/or an integrated gate driver on the printed circuit board 304.

The transistor housing 302 is designed to contain the printed circuit board 304 and enclose it in the assembled state. The transistor housing 302 has first and second housing elements 402 and 404 that are connected to one another, with the printed circuit board 304 embedded between them. The first housing element 402 also has at least one contact window 406, as well as a second contact window 407 in this exemplary embodiment, through which heat from the numerous power transistors 400 can be discharged. The first housing element 402 also has an outer surface 408 facing away from the printed circuit board, which is in the same plane as the cooling surfaces 410 on the power transistors 400. There is a thermal conductor on this plane, which thermally couples the transistor unit 112 to a cooling unit in the power converter.

The printed circuit board 304 has at least one anchoring hole 412, 414, 416, 418, specifically four in in this exemplary embodiment, with which the printed circuit board 304 is held in place between the housing elements 402, 404. The second housing element 404 has at least one insertion hole 420. The first housing element 402 has at least one insertion element that passes through the anchoring hole 412 into the insertion hole 420 to close the transistor housing 302. Because the second housing element 404 in this exemplary embodiment has four insertion holes 420, 424, 426, 428, which correspond to the anchoring holes 412, 414, 416, 418 in the printed circuit board 304, the first housing element 402 also has four insertion elements, only two of which can be seen in the drawing due to the perspective.

In this exemplary embodiment, the second housing element 404 has an optional rib structure 432 on the side facing the printed circuit board 304.

In other words, the transistor unit 112 forms a three-dimensional package for discrete power transistors 306 that can be used in converters (DC/DC, OBC). The structural concept contains at least one top-side cooled (TSC) power transistor 306, which is soldered to the printed circuit board 304 in a pre-assembly process. A snubber capacitor and/or integrated gate driver are placed on the printed circuit board 304 to optimize the switching properties of high-speed power semiconductors (SiC, GaN). The transistor unit 112 is mounted and held in place by the mechanical pressure exerted by the retaining element, or clamp, shown in FIG. 3 on the cooling unit, also referred to as a heatsink. The transistor unit 112 comprises the transistor housing 302 formed by the housing elements 402, 404, which can also be referred to as a frame, and contain plastic, for example.

Low inductance commutation cells for power semiconductors, such as an integrated snubber capacitor, as well as the possibility of driver integration, form the prerequisites for using high-speed power semiconductors made of silicon carbide (SiC) and/or gallium nitride (GaN). They are insulated against the housing parts by a plastic coating.

FIG. 5 shows a schematic sectional view of an exemplary embodiment of a transistor unit 112 such as that in FIGS. 1 to 4, specifically FIG. 3. The thermal conductor 114 for the power converter is also shown in FIG. 5, which bears against the surface of the first housing element 402. The thermal conductor 114 is formed by a laminar structure 500 containing at least one layer.

The laminar structure 500 in this exemplary embodiment comprises three layers A, B, and A′, containing an organic material, a ceramic material, and/or plastic, e.g. silicon with or without a phase-changing property. By way of example, the outer layers A, A′ are made of the same material, or have the same curing characteristics. The middle layer B has either a different curing characteristic, or is made of a different material than the outer layers A, A′.

This means that the middle layer B can be fully cured when it is placed on the transistor unit 112, while the outer layers A, A′ are still semifluid or viscous. This is obtained with injection molding, in which the material in question is superheated. In this case, the thermal conductor 114 is made of an organic insulator. By way of example, because of the different curing characteristics, it is mechanically coupled to the cooling unit. The laminar structure 500 comprises a partially cured organic insulator or a ceramic insulator.

With a ceramic insulator, the middle layer B of the laminar structure 500 contains a ceramic material. The outer layers A, A′ form thermal conductive layers made of the same material, forming a thermal interface material (TIM), which differs from that of the middle layer B. By way of example, the outer layer A is partially or entirely made of metal, to obtain a mechanical anchoring, and the layer A′ forms a cooling layer.

The thermal conductor 114 also has another insulating material with which it is thermally attached to the heatsink.

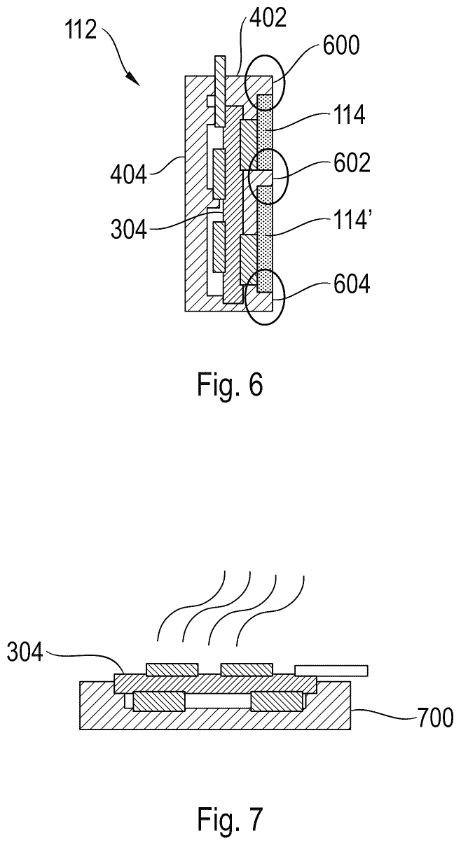

FIG. 6 shows a schematic sectional view of an exemplary embodiment of a transistor unit such as that shown in FIGS. 1 to 5, which is particularly similar to that in FIG. 5. The housing element 402 in this exemplary embodiment has numerous projections 600, 602, 604, which form spacers protruding from the same plane. The thermal conductor 114 forming an intermediate layer for thermally coupling the transistor unit 112 to the cooling unit in the power converter is placed between the projections 600, 602, 604. More precisely, the first housing element 402 in this exemplary embodiment has three projections. The thermal conductor 114 comprises numerous parts and the thickness thereof corresponds to the height of the projections 600, 602, 604.

By way of example, the thermal conductor 114 in this exemplary embodiment forms a filler insulating against the cooling unit. The filler is placed between the projections 600, 602, 604 while it is still liquid. The thermal conductor 113 therefore contains the insulating material forming a gap filler, and is placed on a frame defined by the projections 600, 602, 604 to establish the thickness thereof.

FIGS. 7 to 11 show individual steps of a joining process for an exemplary embodiment of the transistor unit shown in any of the FIGS. 1 to 6.

FIG. 7 shows a schematic illustration of an exemplary embodiment of a printed circuit board 304 corresponding, or at least similar, to the printed circuit board in any of the FIGS. 3 to 6. In this exemplary embodiment, the printed circuit board 304 is not yet placed in the transistor housing. Instead, a first step of the joining process is illustrated here, in which the individual components, e.g. numerous power transistors 306, are soldered onto the printed circuit board 304. The printed circuit board 304 is placed on an assembly tool 700 for this.

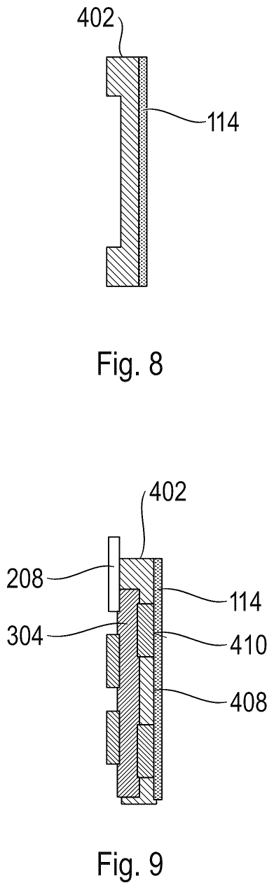

A schematic illustration of the first housing element 402 is shown in FIG. 8, on which the thermal conductor 114 can be placed, as shown here.

The printed circuit board 304 is then placed in the first housing element 402 in FIG. 9, such that the cooling surfaces 410 of the power transistors 306 form a plane with the outer surface 408 of the first housing element 402.

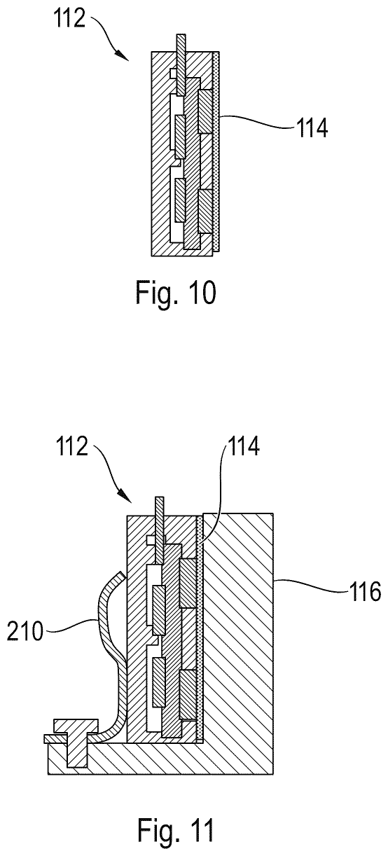

The transistor unit 112 is fully assembled in FIG. 10. The thermal conductor 114 is also placed on the first housing element 402, as shown in FIGS. 8 and 9.

The transistor unit 112, with the thermal conductor 114, is then placed in the power converter, as shown in FIG. 11. The transistor unit 112 is pressed against the cooling unit 116 by the retaining element 210 at this point, as shown by way of example in FIGS. 2 and 3.

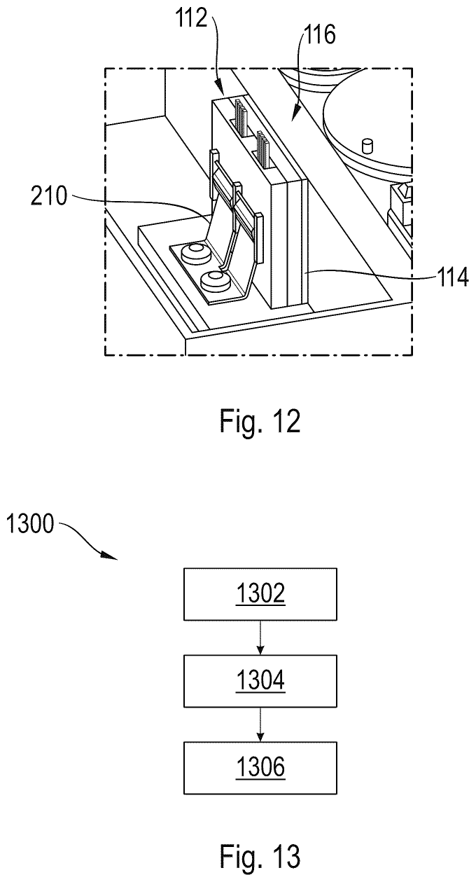

FIG. 12 shows a schematic illustration of an exemplary embodiment of an assembled transistor unit 112 such as that described, or at least mentioned, in reference to FIGS. 1 to 11. More precisely, the transistor unit 112 is connected to the cooling unit 116 by the thermal conductor 114 in FIG. 12, as described above in reference to FIGS. 2, 3, and 11.

FIG. 13 shows a flow chart of a method 1300 for the production of a power converter for a vehicle such as that shown in FIG. 1. The method 1300 comprises a step 1302 in which the transistor unit is assembled, in which a printed circuit board in the transistor unit is populated with numerous power transistors, and embedded between the first housing element and second housing element of the transistor unit. The method 1300 also comprises a step 1304 in which the thermal conductor is placed on the plane of the transistor unit. The method 1300 also comprises a step 1306 in which the transistor unit is coupled to a cooling unit by the thermal conductor to obtain the power converter.

The exemplary embodiments shown in the figures are just examples. Different exemplary embodiments can be combined entirely with one another, or just with regard to individual features. Furthermore, one exemplary embodiment can be supplemented by the features of another exemplary embodiment.

The steps of the method can also be repeated or carried out in a sequence other than that described herein.

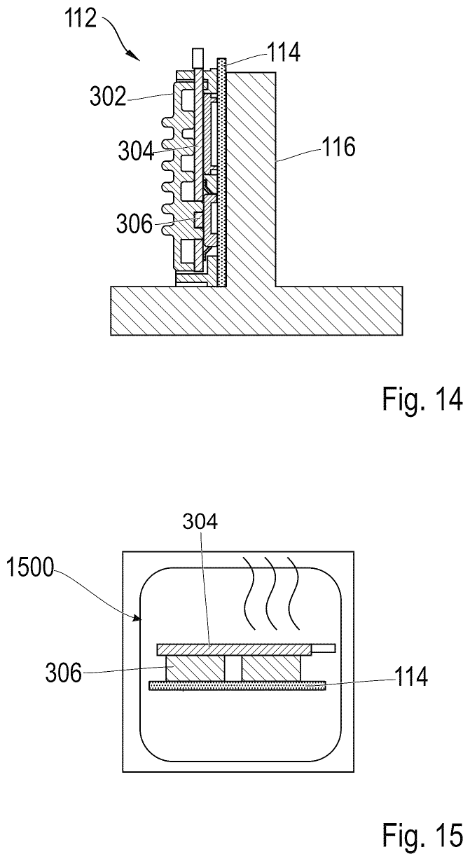

FIG. 14 shows a schematic illustration of an exemplary embodiment of a printed circuit board in a transistor unit 112, which is similar to that described or mentioned in reference to FIGS. 1 to 13. The transistor housing 302 at least partially houses the printed circuit board 304 in this exemplary embodiment. This means that the transistor housing 302 is on a side of the printed circuit board 304 facing away from the cooling unit 116. There are power transistors 306 on the other side of the printed circuit board, which come in contact with the thermal conductor. The thermal conductor 114 in this exemplary embodiment contains a metallized ceramic substrate. This means that the supporting substrate contains ceramic, to which a copper layer is applied to obtain a mechanical bond and thermal connection. The power transistors 306 are soldered to the thermal conductor 114, which forms a metalized ceramic insulator. Uniform pressure is applied, and tolerances are compensated for.

FIG. 15 shows a schematic illustration of an exemplary embodiment of a printed circuit board module 1500 in a transistor unit. More precisely, a step in a joining process for producing the printed circuit board module 1500 is shown, which is part of the transistor unit described or at least mentioned in reference to FIGS. 1 to 14. A soldering process is shown in this exemplary embodiment, in which the power transistors populating the printed circuit board 304 are soldered to the thermal conductor 114, thus forming the printed circuit board module 1500.

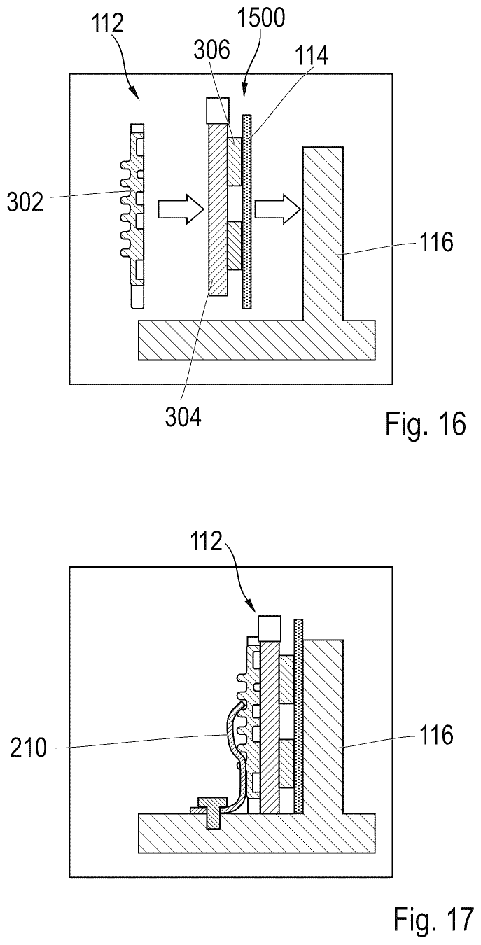

FIG. 16 shows a schematic exploded view of an exemplary embodiment of a transistor unit 112 such at that described or at least mentioned in reference to FIGS. 1 to 15. In this exemplary embodiment, the transistor housing 302 is attached to one side of the printed circuit board 304 in the printed circuit board module 1500. The printed circuit board 304 is soldered to the thermal conductor 114, as explained in reference to FIG. 15. The printed circuit board module 1500 is then placed on the cooling unit 116, such that the thermal conductor 115 is in contact with the cooling unit 116 in the assembled state.

FIG. 17 shows a schematic illustration of an exemplary embodiment of a transistor unit 112 such as that described or at least mentioned in reference to FIGS. 1 to 16. The transistor unit 112 in this exemplary embodiment is placed in the power converter, as explained in particular in reference to FIGS. 15 and 16. This means that the transistor unit 112 is shown in the assembled state, and pressed against the cooling unit 116 by the retaining element 210.

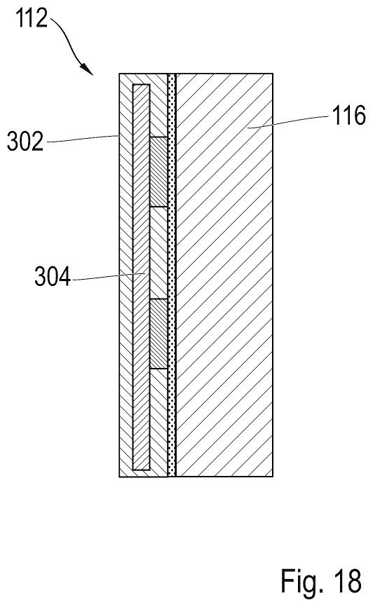

FIG. 18 shows a schematic illustration of an exemplary embodiment of a transistor unit 112, which is similar to the transistor unit described or mentioned in FIGS. 1 to 17. The transistor housing 302 in this exemplary embodiment is formed by a component that encapsulates the printed circuit board 304 and the power transistors populating it. By way of example, the encapsulating component contains a plastic, e.g. a thermosetting material, which is applied to the printed circuit board 304 in an injection molding process. This application replaces the function of a plastic retainer, and also functions as an insulation. To improve the thermal bond, this is a thermally optimized application, containing thermally conductive fillers with which the heat generated in the transistor unit 112 is transferred to the cooling unit 116.

If an exemplary embodiment contains an “and/or” conjunction between a first and second feature, this can be read to mean that a first embodiment contains both the first and second feature, and a second embodiment contains only the first or second feature.

### REFERENCE SYMBOLS

100 motor vehicle
102 electric axle drive
104 electric machine
106 transmission
108 power converter
110 power supply
112 transistor unit
114 thermal conductor
114′ thermal conductor
116 cooling unit
118 power converter housing
200 transverse rib
202 electrical components
204 chamber
206 chamber
208 electrical wiring
210 retaining unit
212 power converter base
300 plane
302 transistor housing
304 printed circuit board for the transistor unit
306 power transistor
308 printed circuit board for the power converter
310 coil unit
312 cup-shaped area
400 numerous power transistors
402 first housing element
404 second housing element
406 contact window
407 second contact window
408 outer surface
410 cooling surface
412 anchoring hole
414 anchoring hole
416 anchoring hole
418 anchoring hole
420 insertion hole
422 insertion element
424 insertion hole
426 insertion hole
428 insertion hole
430 insertion element
432 rib structure
500 laminar structure
A outer layer
B middle layer
A′ outer layer
600 projection
602 projection
604 projection
700 assembly tool
1300 method for the production of a power converter
1302 step for assembling the transistor unit
1304 step for coupling the transistor unit to the cooling unit
1500 printed circuit board module

1. A transistor unit for a power converter comprising:
a printed circuit board populated with a plurality of power transistors, wherein the printed circuit board has at least one electrical wire connecting the transistor unit within the power converter;
a thermal conductor on the power transistors coupling the transistor unit to a cooling unit for the power converter; and
a transistor housing configured to at least partially house the printed circuit board.

2. The transistor unit according to claim 1, wherein the transistor housing comprises at least one housing element.

3. The transistor unit according to claim 1,
wherein the transistor housing has a first housing element and a second housing element connected to the first housing element,
wherein the printed circuit board is embedded between the first housing element and the second housing element,
wherein the first housing element has at least one contact window that exposes the power transistors,
wherein the first housing element has an outer surface facing away from the printed circuit board that is in a same plane as cooling surfaces of the power transistors, and
wherein the thermal conductor is configured to be placed on the plane.

4. The transistor unit according to claim 3,
wherein the printed circuit board comprises at least one anchoring hole configured to secure the printed circuit board in place between the first housing element and the second housing element,
wherein the second housing element comprises at least one insertion hole, and
wherein the first housing element comprises at least one insertion element that is configured to be inserted into the insertion hole through the at least one anchoring hole to close the transistor housing.

5. The transistor unit according to claim 3,
wherein the first housing element comprises a plurality of projections protruding from a single plane to form spacers,
wherein the thermal conductor forms an intermediate layer configured to thermally couple the transistor unit to a cooling unit in the power converter between the plurality of projections.

6. The transistor unit according to claim 1,
wherein the transistor housing at least partially encapsulates the printed circuit board and the power transistors, and/or
wherein the transistor housing contains thermally conductive fillers.

7. The transistor unit according to claim 1, comprising:
a snubber capacitor on the printed circuit board.

8. The transistor unit according to claim 1, comprising:
an integrated gate driver on the printed circuit board.

9. The transistor unit according to claim 1,
wherein the thermal conductor comprises a laminar structure with at least one layer, wherein the laminar structure contains an organic material, a ceramic material, a metallic material, a metallized ceramic, and/or a plastic.

10. The transistor unit according to claim 9,
wherein the laminar structure comprises three layers, wherein a middle layer contains a different material than outer layers.

11. The transistor unit according to claim 9,
wherein the laminar structure comprises three layers, wherein a middle layer has a different curing characteristic than outer layers.

12. A power converter for a vehicle comprising:
the transistor unit according to claim 1; and
a cooling unit configured to cool the transistor unit, wherein the thermal conductor for the transistor unit is placed on the cooling unit.

13. The power converter according to claim 12, comprising:
a power converter housing,
wherein the transistor unit is placed in the power converter housing, and
wherein the cooling unit forms part of the power converter housing, or is integrated in the power converter housing.

14. The power converter according to claim 12, comprising:
a retaining element configured to retain the transistor unit in the power converter,
wherein the retaining element is configured to press the transistor unit against the cooling unit.

15. An electric axle drive for a motor vehicle comprising:
at least one electric machine;
a transistor; and
the power converter according to claim 12.

16. A motor vehicle comprising:
the electric axle drive according to claim 15.

17. A method of producing a power converter comprising:
assembling a transistor unit, wherein a printed circuit board in the transistor unit is populated with a plurality of power transistors, wherein the printed circuit board is at least partially contained in a transistor housing, and a thermal conductor is placed on the plurality of power transistors; and
coupling the transistor unit to a cooling unit with the thermal conductor to produce the power converter.
